(19) United States
(12) Patent Application Publication
(10) Pub. No.: US 2015/0036415 A1
(43) Pub. Date: Feb. 5, 2015

(54) NON-VOLATILE MEMORY CELL

(71) Applicants: Commissariat à l'Energie Atomique et aux Energies Alternatives, Paris (FR); CENTRE NATIONAL DE LA RECHERCHE SCIENTIFIQUE, Paris Cedex 16 (FR)

(72) Inventors: Grégory DI PENDINA, ECHIROLLES (FR); Kotb JABEUR, L'ARBRESLE (FR)

(21) Appl. No.: 14/446,044

(22) Filed: Jul. 29, 2014

(30) Foreign Application Priority Data
Jul. 30, 2013 (FR) 13/57536

(51) Int. Cl. G11C 13/00; G11C 11/16

(52) U.S. Cl. CPC G11C 13/004; G11C 11/1673; G11C 13/0069; G11C 11/1675
USPC 365/148; 365/158

(57) ABSTRACT

The invention concerns a memory device comprising: a memory cell having at least one resistive memory element (202) with first, second and third terminals (A, B, C), a resistance between the third terminal (C) and one or both of the first and second terminals being programmable to have one of at least two resistive states (Rₘᵢₙ, Rₘₐₓ); and control circuitry (204) adapted: during a write phase of the resistive memory element, to program the resistive state by driving a current between the first and second terminals; and during a read phase of the resistive memory element, to apply a voltage between the third terminal and at least one of the first and second terminals to generate a current through the first resistive memory element that is proportional to the programmed resistive state.

### FIELD

The present application relates to the field of non-volatile memories, and in particular to a non-volatile memory cell and method of writing data to and reading data from such a cell.

### BACKGROUND

It has been proposed to use programmable resistive elements in memory cells to provide non-volatile data storage. Such resistive memory elements are programmable to adopt one of a plurality of different resistive states. The programmed resistive state is maintained even when a supply voltage of the memory cell is disconnected, and therefore data can be stored by such elements in a non-volatile fashion.

Various types of resistive memory elements have been proposed, some of which are capable of being programmed by the direction of a current that is passed through the resistive elements. An example of such a current-programmable resistive element is an STT (spin transfer torque) element, which is based on magnetic tunneling junctions (MTJs).

Such resistive memory elements generally comprise two terminals, and are programmed by driving a current in one direction or the other between the two terminals. To read the programmed value, a voltage is applied across the two terminals, and the level of the current that is generated is detected.

A drawback of known resistive memory elements having just two terminals is that, particularly in the case where there is a relatively large number of such memory elements grouped together, the current density during read operations can cause erroneous switching of one or more of the memory cells, leading to data loss.

### SUMMARY

It is an aim of embodiments of the present description to at least partially address one or more drawbacks in the prior art.

According to one aspect, there is provided a memory device comprising: a memory cell comprising at least one resistive memory element having first, second and third terminals, a resistance between said third terminal and one or both of said first and second terminals being programmable to have one of at least two resistive states; and control circuitry adapted: during a write phase of said resistive memory element, to program the resistive state by driving a current between said first and second terminals; and during a read phase of said resistive memory element, to apply a voltage between said third terminal and at least one of said first and second terminals to generate a current through the first resistive memory element that is proportional to the programmed resistive state.

According to one embodiment, driving a current between said first and second terminals comprises: driving a current from said first terminal to said second terminal to program a first resistive state of said resistive memory element; or driving a current from said second terminal to said first terminal to program a second resistive state of said resistive memory element.

According to one embodiment, the resistive memory element comprises a conduction layer comprising said first and second terminals, and a programmable resistive stack formed over said conduction layer and comprising said third terminal.

According to one embodiment, the resistive element is of the spin orbit torque magnetic tunnel junction (SOT-MTJ) type.

According to one embodiment, the memory device comprises a further resistive memory element having first, second and third terminals, a resistance between said third terminal and one or both of said first and second terminals of said further resistive memory element being programmable to have one of at least two resistive states, wherein the first terminals or second terminals of said resistive memory element and said further resistive memory element are coupled together.

According to one embodiment, the first terminals or second terminals are coupled together via an intermediate node, said memory cell further comprising a transistor coupled between the intermediate node and a read voltage level, wherein during said read phase said control circuitry is adapted to activate said transistor to apply a voltage between said third terminal and at least one of said first and second terminals.

According to one embodiment, the memory device further comprises a latch having: a first input node coupled to the third terminal of the resistive memory element; and a second input node coupled to the third terminal of said further resistive memory element.

According to one embodiment, the latch further comprises first and second inverters cross-coupled between said first and second input nodes.

According to one embodiment, the first inverter comprises a single transistor, coupled between said first input node and a first supply voltage ; the second inverter comprises a single transistor, coupled between said second input node and said first supply voltage; and the latch further comprises a third transistor coupled between said first input terminal and a second supply voltage and adapted to have a lower threshold voltage than the single transistor of said first inverter, and a fourth transistor coupled between said second input terminal and said second supply voltage, and adapted to have a lower threshold voltage than the single transistor of said second inverter.

According to one embodiment, the latch further comprises a fifth transistor coupled between the first input node and a data input of the latch, the fifth transistor being controlled by a clock signal.

According to one embodiment, the memory device further comprises a sixth transistor coupled between said first and second input nodes and activated during a portion of said read phase.

According to one embodiment, the memory device comprises an array of said memory cells, said array comprising a plurality of rows of said memory cells and a plurality of columns of said memory cells. According to one embodiment, the array comprises:

first row/column lines each coupled to the first terminal of said at least one resistive memory element of each memory cell of a corresponding row or column of said array; second row/column lines each coupled to the second terminal of said at least one resistive memory element of each memory cell of a corresponding row or column of said array; and third row/column lines each coupled to the third terminal of said at least one resistive memory element of each memory cell of a corresponding row or column of said array.

According to one embodiment, each memory cell of the array further comprises a first transistor coupled between the first terminal of said at least one resistive memory element and a corresponding first row/column line, wherein said control circuitry is adapted to activate said first transistor of a memory cell to be read during said write phase.

According to one embodiment, each memory cell of the array further comprises a second transistor coupled between the third terminal of said at least one resistive memory element and a corresponding third row/column line, the control circuitry being adapted to activate said second transistor of a memory cell to be read during said read phase.

According to a further aspect, there is provided a method of programming a memory cell comprising at least one resistive memory element having first, second and third terminals, a resistance between said third terminal and one or more of said first and second terminals being programmable to have one of at least two resistive states; and control circuitry, the method comprising: during a write phase of the resistive memory element, programming, by said control circuitry, said resistive state by driving a current between said first and second terminals; and during a read phase of said resistive memory element, applying, by said control circuitry, a voltage between said third terminal and at least one of said first and second terminals to generate a current through the first resistive memory element that is proportional to the programmed resistive state.

According to one embodiment, the memory cell further comprises a further resistive memory element having first, second and third terminals, a resistance between said third terminal and one or both of said first and second terminals of said further resistive memory element being programmable to have one of at least two resistive states, the method comprising, during said write phase, programming said resistive state of said further resistive memory element by driving a current between said first and second terminals.

### BRIEF DESCRIPTION OF THE DRAWINGS

The foregoing and other features and advantages will become apparent from the following detailed description of embodiments, given by way of illustration and not limitation with reference to the accompanying drawings, in which:

FIG. 1 is a perspective view of a resistive memory element according to an example embodiment of the present disclosure;

FIG. 2A schematically illustrates a memory device based on the resistive memory element of FIG. 1 according to an example embodiment;

FIGS. 2B and 2C are timing diagrams illustrating signals in the circuit of FIG. 2A during a write and read operation;

FIG. 3A illustrates a memory device according to a further embodiment of the present disclosure;

FIG. 3B illustrates the memory device of FIG. 3A in more detail according to one example;

FIG. 3C illustrates a latch of the memory device of FIG. 3A according to one example;

FIGS. 4A to 4D are timing diagrams showing signals in the circuit of FIG. 3B during read and write operations;

FIG. 5A illustrates a memory array according to an example embodiment of the present disclosure; and

FIG. 5B illustrates a memory cell of the memory array of FIG. 5A in more detail according to an example embodiment of the present disclosure.

### DETAILED DESCRIPTION

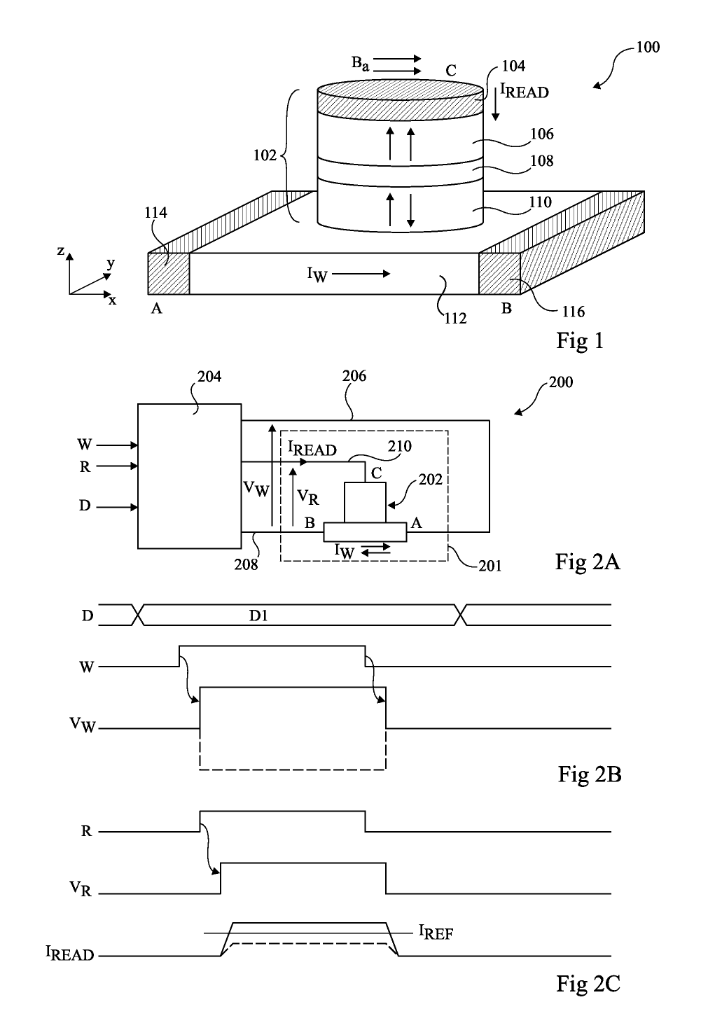

FIG. 1 illustrates, in perspective view, a resistive memory element 100 according to an example embodiment.

The resistive element 100 is for example a spin-orbit torque magnetic tunnel junction (SOT-MTJ). Such a device is for example described in more detail in the publication titled “Voltage and Energy-Delay Performance of Giant Spin Hall Effect Switching for Magnetic Memory and Logic”, S. Manipatruni et al., and in the publication titled “Spin-Torque Switching with the Giant Spin Hall Effect of Tantalum”, Luqiao Liu et al., DOI: 10.1126/science.1218197 Science 336, 555 (2012), the contents of these publications being hereby incorporated by reference to the extent allowable by the law.

The resistive memory element 100 comprises three connection terminals, labeled A, B and C in FIG. 1. The terminal C is part of a resistive stack 102, which comprises an electrode 104 formed over a reference nano-magnet layer 106. Layer 106 is in turn formed over an insulator layer 108, and layer 108 is in turn formed over a storage nano-magnet layer 110.

The reference layer 106 corresponds to a magnetic layer in which the direction of magnetization is fixed. The storage layer 110 on the contrary corresponds to a magnetic layer in which the direction of magnetization can be controlled. The resistive stack 102 is formed over a conducting layer 112, which provides the interface for programming the direction of magnetization of the storage layer 110. The conducting layer 112 is for example formed of: β-tantalum (β-Ta); β-tungsten (β-W); and/or platinum (Pt), and for example comprises, at opposing ends, an electrode 114 forming a terminal A of the element 100 and an electrode 116 forming a terminal B of the element 100. The electrodes 114, 116 are for example each formed of copper, or another suitable material.

As shown by arrows Bₐ in FIG. 1, a static magnetic field, for example provided by a permanent magnet or a bias layer, is for example present close to the reference layer 106. Such a magnetic field is for example discussed in more detail in the publication titled “Perpendicular switching of a single ferromagnetic layer induced by in-plane current injection” loan mihai Miron et al., Nature 476, 189-193, DOI: 10.1038/nature10309.11, August 2011, the contents of which is hereby incorporated by reference to the extent allowable by the law.

During a write operation, a current is applied from the terminal A towards the terminal B, or in the opposite direction, in order to program the direction of magnetization in the storage layer 110. As shown by arrows x, y, and z in FIG. 1, the direction of the write current I_{W} flowing through the conducting layer 112 from terminal A to towards terminal B will be called the +x direction, the direction perpendicular to +x direction in the plane of the conducting layer will be called the +y direction, and the upward direction perpendicular to +x and +y directions will be called the +z direction. A positive write current I_{W} in the +x direction will produce a spin injection current with transport direction in the +z direction, and spins pointing in the +y direction. The injected spin current in the +z direction will in turn produce spin torque to align the magnet in the +y direction. A negative write current I_{W} in the −x direction will produce a spin injection current with transport direction in the −z direction, and spins pointing in the −y direction. The injected spin current in the −z direction will in turn produce spin torque to align the magnet in the −y direction.

When the direction of magnetization in the storage layer 110 is the same as that of the reference layer 106, the resistance of the resistive stack 102 is for example at a relatively low value Rₘᵢₙ. When the direction of magnetization in the storage layer 110 is opposite to that of the reference layer 106, the resistance of the resistive stack 102 is for example at a relatively high value Rₘₐₓ.

It will be apparent to those skilled in the art that the structure represented in FIG. 1 provides just one example of a possible structure of a three-terminal programmable resistive element. In alternative embodiments, one or more additional layers could be included, and different combinations of materials could be used. Furthermore, it will be apparent to those skilled in the art that an additional read node could be provided, for example on the underside of the conducting layer 112, or elsewhere, such that the electrodes 114 and 116 are used exclusively for writing.

FIG. 2A illustrates a memory device 200 based on a three-terminal resistive memory element according to an example embodiment.

The memory device 200 comprises a non-volatile memory cell 201, which for example comprises a single programmable resistive element 202 having the same structure as that of

FIG. 1. In alternative embodiments described in more detail below, the memory cell 201 could comprise a plurality of programmable resistive elements.

The memory device 200 further comprises control circuitry 204, which receives a write signal W, a read signal R, and data signal D. Furthermore, the circuitry 204 has output lines 206 and 208 coupled to the terminals A and B respectively of the resistive memory element 202, and a further output line 210 coupled to the terminal C of the resistive memory element 202.

During a write phase of the resistive memory element 202, the control circuitry 204 for example applies a voltage V_{W} between the lines 206 and 208, which may be a positive or negative voltage, thereby generating a positive or negative write current I_{W} between the terminals A and B of the resistive memory element 202.

An example of the operation of the memory device 200 during a write operation will now be described in more detail with reference to the timing diagram of FIG. 2B.

FIG. 2B illustrates signals D and W, and the voltage V_{W}, in the circuit of FIG. 2A during a write operation.

During a write operation, the data signal D for example provides one bit of data D1 to be stored by the resistive memory element 202.

The write signal W for example goes from a low state to a high state to start the write phase. This for example triggers, a short time later, a write voltage V_{W} between the output lines 206 and 208 of the control circuit 204, this voltage being positive or negative depending on the data value D1. In the example of FIG. 2B, the write voltage V_{W} is positive, generating a positive current in the device 202 from the terminal A towards the terminal B, and programming a first state of resistance, which is for example state Rₘᵢₙ. In an alternative example shown by a dashed line in FIG. 2B, the write voltage V_{W} could be negative, implying that the positive voltage is applied to the line 208, and a ground voltage to the line 206, and a current flows from the terminal B towards the terminal A.

Referring again to FIG. 2A, during a read phase, the control circuitry 204 for example applies a voltage V_{R} between the lines 206 and/or 208 and the line 210. The read current generated by this voltage is for example in the direction of line 210 towards line 208/206. Alternatively, the read current could be in the opposite direction. In either case, the control circuitry 204 for example comprises means for detecting the level of the read current I_{READ} on the line 206, 208 or 210 in order to detect the programmed resistive state held by the resistive memory element 202.

An example of the operation of the memory device 200 during a read operation will now be described in more detail with reference to the timing diagram of FIG. 2C.

FIG. 2C illustrates signals in the circuitry of FIG. 2A during a read operation according to an example embodiment.

The read signal R for example goes high at the start of the read phase, triggering the application of the read voltage V_{R}, for example between the terminal C and one or both of the terminals A and B of the resistive element, in order to generate a write current through the device that passes through the resistive stack 102.

FIG. 2C also illustrates an example of the read current I_{READ}, which rises to a stable level shortly after the read voltage is applied. As shown by a solid line in FIG. 2C, the read current for example rises to a high level in the case that resistance has been programmed to have a value Rₘᵢₙ, or to a lower value shown by a dashed line if the resistance has been programmed to have a value Rₘₐₓ. A reference current, for example at a level halfway between the high and low currents in FIG. 2C, is for example compared by the control circuitry 204 with the read current I_{READ} in order to detect whether the current is higher or lower than I_{READ}.

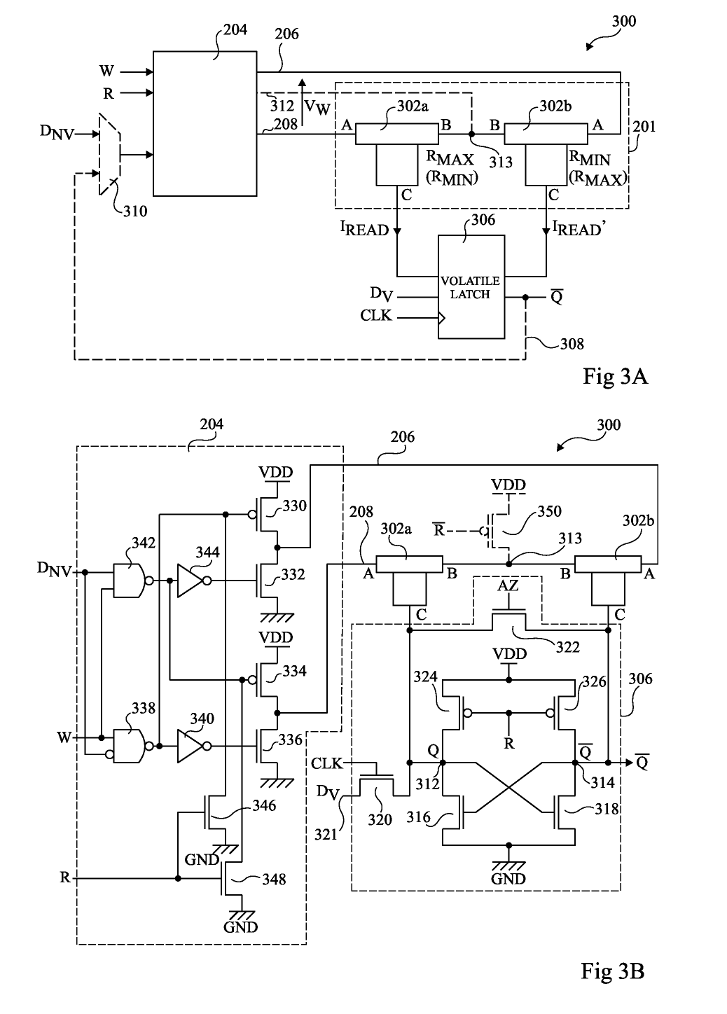

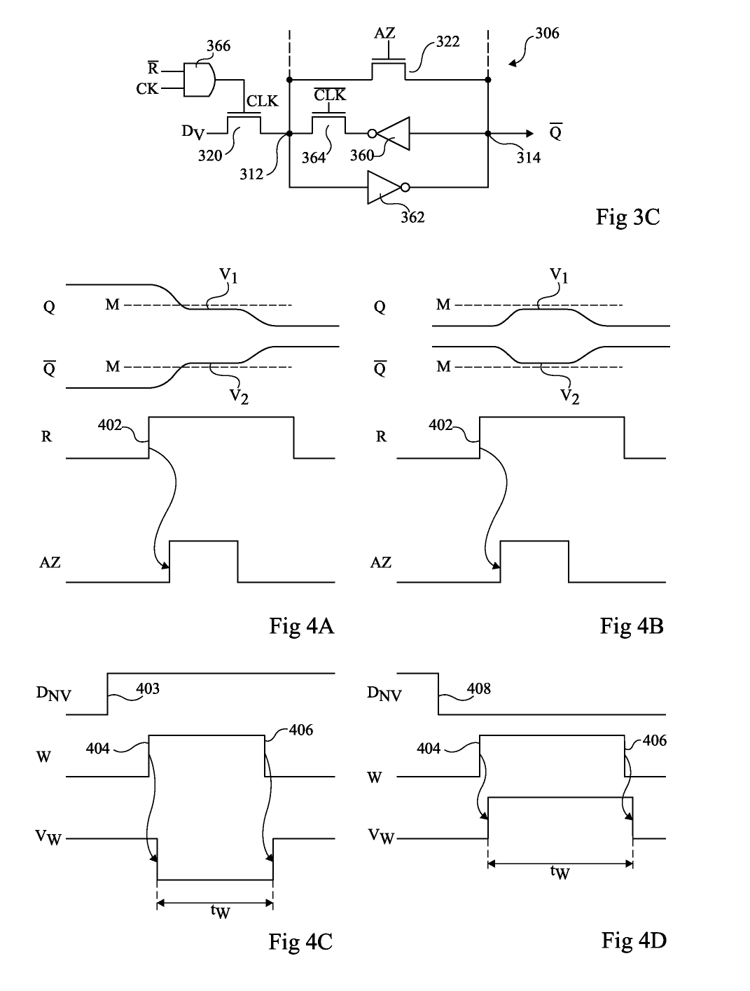

FIG. 3A schematically illustrates the memory device 300 according to a variant similar to the memory device of FIG. 2A, in which the memory cell 201 comprises a pair of resistive memory elements 302a and 302b programmed in a complementary fashion to store a data bit. Furthermore, in the example of FIG. 3A, the memory device 300 forms data latch, comprising a volatile latch 306 coupled to the resistive memory elements 302a, 302b.

The resistive elements 302a, 302b are coupled in series via their terminals A, B between the output lines 206, 208 of the control circuit 204. The resistive terminal C of each of the elements 302a, 302b is coupled to a respective input node of the volatile latch 306. The volatile latch 306 also for example receives volatile data Dᵥ and a clock signal CLK, and provides a data output Q̅.

As shown by a dashed line 308 in FIG. 3A, in some embodiments the data output Q̅ is fed to the non-volatile data input of the control circuit 304, for example via a multiplexer 310, such that data stored by the latch 306 in a volatile fashion may be stored in a non-volatile fashion by the resistive memory elements 302a, 302b. The multiplexer 310 for example allows a selection to be made between the data at the output of the latch 306, and non-volatile date D_{NV} to be written to the resistive memory elements 302a, 302b during a write operation.

As shown by a dashed line 312 in FIG. 3A, in some embodiments the read voltage V_{R} could be applied to an intermediate node 313 between the resistive memory elements 302a, 302b.

In operation, the volatile latch 306 may operate as a standard latch independent of the resistive memory elements 302a, 302b, latching the data D_{V} during high pulses of the clock signal CLK, and for example providing the inverse of the data signal at its Q̅ output. During this operation, the read and write signals W and R are for example low, meaning that the control circuitry 204 does not apply any high voltages to the lines 206 or 208.

When a write operation is to be performed, the signal W is asserted, and the write current is generated through the output lines 206 and 208 of the control circuit, passing through both of the resistive memory elements 302a, 302b. The resistive elements are for example coupled in opposite orientations from each other, their B terminals being coupled together in the example of FIG. 3A. In this way, the write current programs the resistive elements 302a, 302b in an opposite manner. During a write operation, the volatile latch may continue to function in a standard fashion by clocking the data signal D_{V}.

When a read operation is to be performed, the read signal R is asserted, and the control circuitry 204 for example asserts the read voltage V_{R} for example by applying a high voltage to each of the output lines 206 and 208, or by applying a high voltage to the intermediate node 313, in order to induce read currents I_{READ} and I_{READ}′ from the terminal C of the elements 302a, 302b respectively to the input nodes of the volatile latch 306. These read currents, and in particular the relative levels of the read currents, program the state stored by the volatile latch 306. During the read operation the clock signal CLK remains low, and the volatile latch 306 provides an output device for the data bit stored by the resistive memory elements 302a and 302b.

FIG. 3B illustrates the circuit of FIG. 3A, and in particular the control circuitry 204 and volatile latch 306, in more detail according to an example embodiment.

The volatile latch 306 for example comprises input nodes 312, 314 respectively coupled to the C terminals of the resistive memory devices 302a, 302b. Inverters, each for example being formed of a single transistor 316, 318, are cross-coupled between the input nodes 312, 314. For example, transistor 316 is an NMOS transistor coupled by its main current nodes between the input node 312 and ground, and transistor 318 is an NMOS transistor coupled by its main current nodes between the input node 314 and ground. The control node of transistor 316 is coupled to the input node 314, and the control node of transistor 318 is coupled to the input node 312.

The volatile latch 306 also for example comprises an input transistor 320, for example an NMOS transistor, coupled between the input node 312 and the data input D_{V}, and controlled by the clock signal CLK. Furthermore, the latch 306 for example comprises a transistor 322, for example an NMOS transistor, coupled between the input nodes 312 and 314, and controlled by a control signal AZ. As will be described in more detail below, such a transistor, which could be omitted, can improve the speed and robustness of read operations.

In some embodiments, the volatile latch may also comprise transistors 324 and 326, which are for example PMOS transistors, and respectively couple the nodes 312 and 314 to the supply voltage VDD. These transistors are for example controlled by the read signal R, such that they are deactivated during the read phase, but activated at other times to maintain the logic levels stored at the input nodes 312 and 314. Alternatively, the transistors 324 and 326 could be permanently deactivated, for example by coupling their gates to the supply voltage VDD, and have threshold voltages lower than those of NMOS transistors 316 and 318 respectively. Thus, in the non-conducting state, the current leakage through transistors 324 and 326 is greater than through transistor 316 or 318, thereby keeping the corresponding node 312 or 314 at a voltage high enough to be seen as a high logic level. In other words, the leakage current I_{offP} flowing through PMOS transistor 324 or 326 when a high voltage is applied to its gate node is greater that the leakage current I_{offN} flowing through the corresponding NMOS transistor 316 or 318 when a low voltage is applied to its gate node. The particular threshold voltages will depend on the technology used. But as an example, the threshold voltages of

PMOS transistors 324, 326 are chosen to be in the range 0.3 to 0.5 V, while the threshold voltages of NMOS transistors 316, 318 are in the range 0.4 to 0.6 V. In any case, the ratio I_{Offp}/I_{Offn} is selected for example to be greater than 25, and preferably greater than 100.

The control block 204 for example comprises a PMOS transistor 330, coupled by its main current nodes between the output line 206 and the supply voltage VDD, an NMOS transistor 332 coupled by its main current nodes between the output line 206 and ground. It also for example comprises a PMOS transistor 334, coupled by its main current nodes between the output line 208 and the supply voltage VDD, an NMOS transistor 336 coupled by its main current nodes between the output line 208 and ground. The control node of transistor 330 is coupled to the output of a NAND gate 338, which receives at one of its inputs the write signal W, and at the other of its inputs the inverse of the input data signal D_{NV}. The output of NAND gate 338 is also coupled via an inverter 340 to the control node of transistor 336. The control node of transistor 334 is coupled to the output of a NAND gate 342, which receives at one of its inputs the data signal D_{NV}, and at the other of its inputs the write signal W. The output of the NAND gate 342 is also coupled to the gate of the transistor 332 via an inverter 344.

The control circuitry 204 also for example comprises an NMOS transistor 346 coupled between the control node of transistor 330 and ground, and a further NMOS transistor 348 coupled between the control node of transistor 334 and ground. Transistors 346, 348 are for example controlled by the read signal R. As an alternative to the transistors 346, 348, the control circuitry 204 could comprise a PMOS transistor 350, controlled by the inverse of the read signal R, and coupled between the intermediate node 313 between resistive elements 302a, 302b and the supply voltage VDD.

Operation of the circuitry of FIG. 3B will now be described in more detail with reference to the timing diagrams of FIGS. 4A, 4B, 4C and 4D.

FIGS. 4A and 4B are timing diagrams showing signals in the memory device of FIG. 2 during a read phase. In particular, FIGS. 4A and 4B illustrate the data signals Q and Q̅ present at the input nodes 312, 314, the read signal R, and the signal AZ.

During a read phase, data is transformed from being represented by the programmed resistive states of the resistive memory elements 302a, 302b to being represented by voltage levels at the input nodes 312, 314 of the volatile latch. Thus the read phase involves setting the levels of the voltages Q and Q̅ based on the programmed resistive states.

In the examples of FIGS. 4A and 4B, it is assumed that the resistive memory element 302a has been programmed to have a high resistance Rₘₐₓ, and the resistive memory element 302b a low resistance Rₘᵢₙ. While not shown in FIGS. 4A and 4B, during the read phase, the signal W is for example low.

FIG. 4A corresponds to a case in which the voltages Q and Q̅ are initially at a high state and low state respectively. The term “high state” is used herein to designate a voltage level close to or at the level of the supply voltage V_{DD}, while the term “low state” is used herein to designate a voltage level close to or at the ground voltage.

The read signal R is for example initially low, such that transistors 330 and 334 are non-conducting. The signal AZ is for example initially low, such that transistor 322 is non-conducting. The read signal R, which is for example initially low, is asserted as shown by a rising edge 402. This causes the transistors 346 and 348 of the control circuitry to be activated, which in turn activates the transistors 330 and 334 to couple the output lines 206 and 208 of the control circuit 204 to the supply voltage. The read signal also triggers a rising edge of the signal AZ, and thus the transistor 322 of the latch is activated. Thus a read current I_{READ} will be induced in the left-hand branch of the latch 306, which flows through the transistor 334, the resistive memory element 302a, and the transistor 316, and a read current I_{READ} will be induced in the right-hand branch of the latch 306, which flows through the transistor 330, the resistive memory element 302b and the transistor 318.

However, due to the difference in the programmed resistances of the resistive memory elements 302a, 302b, the current in the left-hand branch is lower than the current in the right-hand branch. Thus these currents for example cause the voltage at input node 312 to fall and settle at a level V₁ below a level of metastability M, and the voltage at input node 314 to rise to a level V₂ above the level of metastability M. The level of metastability M is a theoretical voltage level approximately halfway between the high and low voltage states, representing the level from which there would be equal probability of Q flipping to the high or low states. Asserting the signal AZ to turn on transistor 322 has the effect of speeding up the descent of the voltage level Q, and the rise of the voltage level Q̅.

The signal AZ is then brought low, such that the levels of Q and Q̅ go to their closest stable state, which in the example of FIG. 4A corresponds to the low Q, high Q̅ state. However, it will be apparent to those skilled in the art that the levels V₁ and V₂, and the final stable state, will depend on factors such as the ON resistances of the transistors 316, 330, 318 and 334. The read signal R for example goes low to end the read phase.

FIG. 4B corresponds to a case in which the voltages Q and Q̅ are initially at a low state and high state respectively. Otherwise, the signals are the same as in the example of FIG. 4A, and will not be described again in detail.

FIGS. 4C and 4D are timing diagrams illustrating examples of the signals D_{NV}, W and the voltage V_{W} in the circuit of FIG. 3B during a write phase of the resistive states of the resistive memory elements 302a and 302b. While not shown in FIGS. 4C and 4D, during the write phase, the read signal R for example remains low.

As illustrated in FIG. 4C, initially the signal W is low, such that the transistors 330 to 336 of the control circuitry 204 are all non-conducting, and the voltage V_{W} is for example at 0 V.

The data signal D_{NV} on the input line of the control circuit 204 is for example first set to the value that is to be programmed. In the example of FIG. 4C, the value is a logic “1”, and the data signal D_{NV} for example starts low, and transitions to a high value at a rising edge 403.

The write signal W then goes high at a rising edge 404, triggering, a short time later, the voltage V_{W} to be asserted in a direction so as to cause a current to flow through the resistive memory elements 302a and 302b in a direction that will program their resistances in accordance with the logic “1” data value that is to be programmed. In the example of the control circuitry of FIG. 3B, a high state of a data value D_{NV} corresponds to a negative value of the voltage V_{W}, in other words a high voltage on line 208, and a low voltage on line 206. This is for example achieved by passing a current from storage node 206, through the resistive elements 202 and 204, to the storage node 210.

After the write current has been applied for a sufficiently long time to set the resistive states of the resistive memory elements 302a, 302b, for example for a duration t_{W} of between 0.1 ns and 20 ns, the signal W is brought low again, such that the write voltage returns to 0 V.

FIG. 4D illustrates an alternative case of a write phase in which the data value to be programmed is a logic “0”, and thus the data signal D_{NV} has a falling edge 408. The other signals are the same as those of FIG. 4C, except that a positive voltage V_{W} is applied rather than a negative voltage.

The transistors 330 to 334 are for example dimensioned such that the write current that is generated is high enough to program the resistive states of elements 302a, 302b. Depending on the type and dimensions of the resistive elements 302a, 302b, such a minimum programming current could for example by anything from 20 μA to 1.5 mA. During a read phase, the read current will flow at most through half of the width of the conducting layer between the terminals A and B, and therefore, there is a relative low risk of undesirable programming of the resistive memory elements 302a, 302b during a read operation.

It will be apparent to those skilled in the art how the circuit of FIG. 3B, in which the transistors 316 and 318 are NMOS transistors, could be adapted to a PMOS implementation, by coupling these transistors to VDD rather than ground, and replacing transistors 324 and 326 by NMOS transistors coupled to ground. In such a case, during a read operation, the terminals A and/or B of the resistive memory elements 302a, 302b, are for example coupled to ground rather than to the supply voltage VDD.

With reference again to FIG. 3B, in some embodiments the transistors 316 and 318 may comprise bulk nodes (not illustrated) allowing their bulk voltages to be controlled. For example, the bulk node of transistors 316 and 318 each receive a bulk voltage V_{BULK}. During a standard operation of the latch 306, the bulk voltage V_{BULK} is set to a level, for example to ground, such that the threshold voltages of the NMOS transistors 316, 318 are greater than the threshold voltages of the PMOS transistors 324 and 326. During the read mode, the bulk voltage V_{BULK} is set to a level, for example to the supply voltage VDD, such that the threshold voltages of the NMOS transistors 316, 318 are decreased, leading to a faster read operation. During the write phase, and at least during the write period t_{W} of FIG. 4C or 4D, the bulk voltage V_{BULK} is for example set to a level lower than ground, for example to −VDD, such that the resistance of the NMOS transistors 316, 318, and in particular of the NMOS transistor that is ON, is increased, thereby lowering leakage of the write current. Indeed, in this way, more of the write current will flow through the terminals A and B of the resistive elements 302a and 302b during a write operation.

FIG. 3C illustrates the latch 306 of FIG. 3B according to a variant in which the transistors 316, 318 and 324, 326 are replaced by inverters 360 and 362 cross-coupled between the input nodes 312 and 314. The output of the inverter 360 is for example coupled to the input node 312 via an NMOS transistor 364. The transistor 320 is for example controlled by a signal CLK, and the transistor 364 by the inverse of this signal. The signal CLK is provided by an AND gate 366, which for example receives a clock signal CK and the inverse of the read signal R at its input nodes.

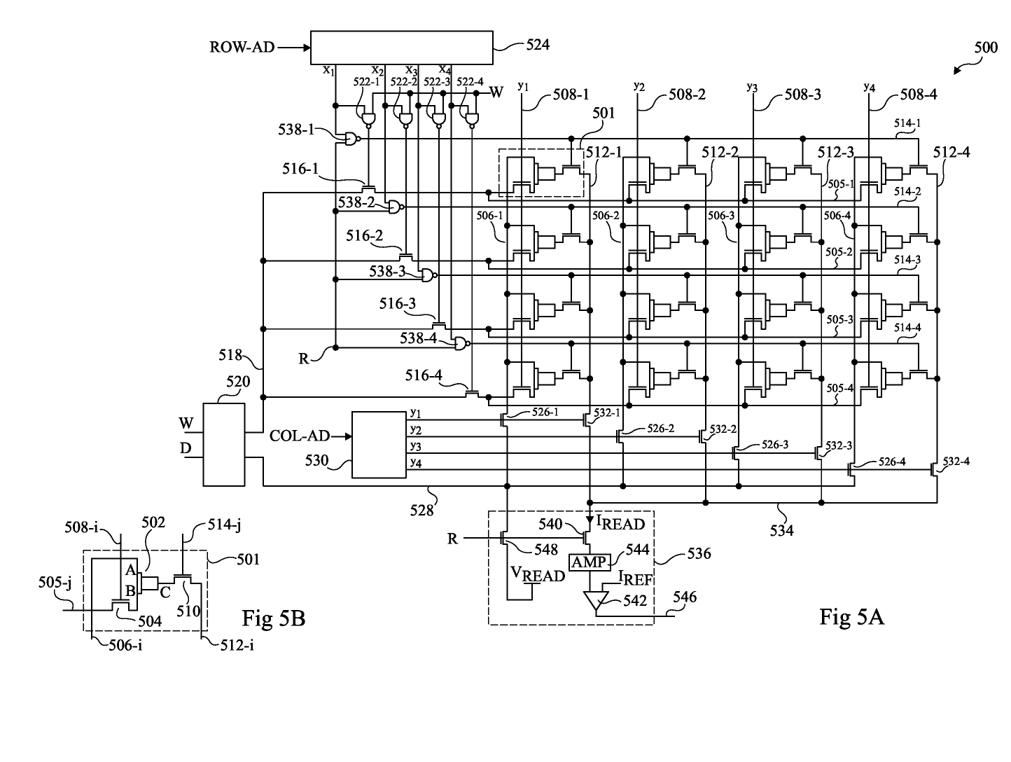

FIG. 5A schematically illustrates a memory array 500 according to an example embodiment.

The memory array 500 comprises array of memory bit-cells 501.

FIG. 5B illustrates one of memory bit-cells 501 in more detail, which for example comprises a resistive memory element 502 as described herein. The memory bit-cell 501 is assumed to be in an ith column and a jth row of the array, and for example comprises a write transistor 504 having one of its main current nodes coupled to a row line 505-j associated with the jth row of the array, and the other of its main current nodes coupled to the terminal B of the resistive element 502. The terminal A is for example coupled to a column line 506-i associated with the ith column of the array. The terminal C of the resistive element 502 is coupled, via the main current nodes of a read transistor 510, to a column line 512-i associated with the ith column of the array. The transistor 510 for example has its control node coupled to a row line 514-j associated with the jth row of the array.

With reference again to FIG. 5A, the array for example comprises four rows and four columns of memory bit-cells, and thus there are four corresponding row lines 505-1 to 505-4 that for example provide write paths to the memory bit-cells, four corresponding column lines 506-1 to 506-4 that for example correspond to source lines, four corresponding column lines 508-1 to 508-4 that for example provide column write signals, four corresponding column lines 512-1 to 512-4 that for example correspond to bit lines, and four corresponding row lines 514-1 to 514-4 that for example provide row read signals.

The row lines 505-1 to 505-4 are each coupled via corresponding transistors 516-1 to 516-4 to an output line 518 of a write block 520. For example, each of the transistors 516-1 to 516-4 has its control node coupled to the output of a corresponding NAND gate 522-1 to 522-4, each of which receives a corresponding output signal x₁ to x₄ from a row decoder 524 at one of its inputs, and a write signal W at the other of its inputs.

The column lines 506-1 to 506-4 are each coupled via a corresponding transistor 526-1 to 526-4 to an output line 528 of the write block 520. For example, each of the transistors 526-1 to 526-4 is controlled by a corresponding output signal y₁ o y₄ of a column decoder 530. Furthermore, each of the column lines 508-1 to 508-4 is for example coupled to receive a corresponding one of the output signals y₁ to y₄.

The column lines 512-1 to 512-4 are each coupled via a corresponding transistor 532-1 to 532-4 to an output line 534, which is in turn coupled to an input of a read block 536. Each of the row lines 514-1 to 514-4 is coupled to the output of a corresponding NAND gate 538-1 to 538-4, each of which has one of its inputs coupled to a corresponding one of the output signals x₁ to x₄ of the row decoder 524, and the other of its inputs coupled to receive a read signal R.

The read block 536 for example comprises a transistor 540 coupled between the line 534 and one input of a comparator 542, for example via an amplifier 544. The other input of the comparator 542 for example receives a reference current I_{REF}. The comparator 542 provides an output signal on a line 546. The read block 536 also for example comprises a transistor 548 coupled between the line 528 and a read voltage V_{READ}, and controlled by the read signal R.

The row decoder and column decoder 524 and 530 for example receive respectively a row address ROW_AD and a column address COL_AD.

The write block 520 for example receives the write signal W, and a data signal D representing data to be written to one or more of the memory bit-cells 501.

In operation, during a write phase, the read signal R is low, and thus the transistors 540 and 548 of the read block 536 and the read transistor 510 of each bit-cell 501 is non-conducting, such that the terminal C of each resistive memory element is floating. Based on the row address and column address signals ROW AD, COL-AD, the memory cell 501 to be written to is selected by activating a corresponding one of the transistors 516-1 to 516-4, a corresponding one of the transistors 526-1 to 526-4 and the write transistors 504 of a column corresponding to the bit-cell 501 to be written. The write signal W also is asserted, and a positive or negative voltage is applied between the output lines 518 and 528 of the write block in order to generate a write current in the appropriate direction based on the data signal D. This operation is for example repeated for all of the memory bit-cells 501 to be written.

During a read operation, the read signal R goes high, and based on the row address and column address signals ROW_AD, COL-AD, the memory cell 501 to be read is selected by activating a corresponding one of the transistors 526-1 to 526-4, a corresponding one of the transistors 532-1 to 532-6, and the read transistors 510 of a row corresponding to the memory bit-cell 501 to be read. The output line 528 is also for example coupled to the read voltage V_{READ} by activating the transistor 548, in order to generate a current I_{READ} through the selected memory cell 501, which can be detected by the read block 536. Based on the level of the detected current I_{READ} with respect to the reference current I_{REF}, the programmed resistive state of the resistive memory element being read can be determined, and thus the signal at the output 546 of the read block 536 indicates the bit value of the stored data. This operation is for example repeated for all of the memory cells 501 to be read.

While the memory bit-cells 501 of FIGS. 5A and 5B each comprise a single resistive element 501, in an alternative embodiment, it will be apparent to those skilled in the art that each memory bit-cell could comprise more than one resistive element, for example two or more elements operating in a complementary fashion.

Furthermore, while the array in FIG. 5A comprises four columns and four rows, it will be apparent to those skilled in the art that in alternative embodiments, the array could comprise more or less than four rows and/or more or less than four columns.

Furthermore, while specific examples of the column and row lines of the memory array have been described, it will be apparent to those skilled in the art that one or more of the column lines could be converted to row lines, and vice versa.

Furthermore, it will be apparent to those skilled in the art that in some embodiments the transistors 516-1 to 516-4, 526-1 to 526-4 and/or 532-1 to 532-4 could be omitted, one or more memory cells to be written to, or a memory cell to be read, being selected only by activating the corresponding write or read transistors 504, 510 of the memory cell. In such a case, the row and column decoders 524, 530 can for example also be omitted, and the write or read transistors 504, 510 of each memory cell are for example controlled by an independent external signal.

An advantage of the embodiments described herein is that the memory cell provides reduced volatility of the stored data and leads to improved reliability by separating the read and write paths. Indeed, the separation of the read and write paths leads to a reduction in the risk of damage, during a read operation, to the resistive memory barrier that stores the memory state. This is due at least in part to the fact that the memory cell comprises a resistive memory element having three terminals, enabling programming of the memory cell by applying a current between two of the terminals (A and B) without crossing the tunnel barrier. Reading on the other hand is performed by detecting the resistance value between the third terminal (C) and one or both of the other two terminals (A and/or C), by detecting the level of a current.

The data retention duration of each memory cell is for example determined by the technological process used to form each memory cell, or by adapting the design of the magnetic tunnel junction to a desired retention time. In some embodiments, the same memory array may comprise resistive elements of different sizes and thus having different retention durations.

Having thus described at least one illustrative embodiment, various alterations, modifications and improvements will readily occur to those skilled in the art.

For example, it will be apparent to those skilled in the art that the supply voltage VDD in the various embodiments could be at any level, for example between 1 and 3 V, and rather than being at 0 V, the ground voltage can also be considered as a supply voltage that could be at any level, such as a negative level.

Furthermore, it will be apparent to those skilled in the art that, in any of the embodiments described herein, all of the NMOS transistors could be replaced by PMOS transistors and/or all of the PMOS transistors could be replaced by NMOS transistors. It will be apparent to those skilled in the art how any of the circuits could be implemented using only PMOS or only NMOS transistors. Furthermore, while transistors based on MOS technology are described throughout, in alternative embodiments other transistor technologies could be used, such as bipolar technology.

Furthermore, it will be apparent to those skilled in the art that the various features described in relation to the various embodiments could be combined, in alternative embodiments, in any combination.

1. A memory device comprising:
an array of memory cells associated with a control circuitry, wherein:
each memory cell comprises at least one resistive memory element (202, 302a, 302b, 502) having first, second and third terminals (A, B, C), a resistance between said third terminal (C) and at least one of said first and second terminals being programmable to have one of at least two resistive states (Rmin, Rmax);
the control circuitry (204) is adapted:
during a write phase of said at least one resistive memory element, to program the resistive state by driving a current between said first and second terminals; and
during a read phase of said at least one resistive memory element, to apply a voltage between said third terminal and at least one of said first and second terminals to generate a current through said at least one resistive memory element that is proportional to the programmed resistive state;
said array comprises:
a plurality of first row/column lines (505-1 to 505-4) wherein each first row/column line of the plurality of first row/column lines is coupled to the first terminal of said at least one resistive memory element of each memory cell of a row or column of said array corresponding to the first row/column line;
a plurality of second row/column lines (506-1 to 506-4) wherein each second row/column line of the plurality of second row/column lines is coupled to the second terminal of said at least one resistive memory element of each memory cell of a row or column of said array corresponding to the second row/column line; and
a plurality of third row/column lines (512-1 to 512-4) wherein each third row/column line of the plurality of third row/column lines is coupled to the third terminal of said at least one resistive memory element of each memory cell of a row or column of said array corresponding to the third row/column line; and
each memory cell of the array further comprises a first transistor (504) coupled between the first terminal of said at least one resistive memory element and a corresponding first row/column line, wherein said control circuitry is adapted to activate said first transistor of a memory cell to be read during said write phase.

2. The memory device of claim 1, wherein driving a current between said first and second terminals comprises at least one of:
driving a current from said first terminal to said second terminal to program a first resistive state of said at least one resistive memory element; and
driving a current from said second terminal to said first terminal to program a second resistive state of said at least one resistive memory element.

3. The memory device of claim 1, wherein said at least one resistive memory element comprises a conduction layer (112) comprising said first and second terminals, and a programmable resistive stack (102) formed over said conduction layer and comprising said third terminal.

4. The memory device of claim 1, wherein said at least one resistive element is of the spin orbit torque magnetic tunnel junction (SOT-MTJ) type.

5. The memory device of claim 1, comprising a second resistive memory element (302b) having first, second and third terminals (A, B, C), a resistance between said third terminal (C) of said second resistive memory element and at least one of said first and second terminals of said second resistive memory element being programmable to have one of at least two resistive states (Rₘᵢₙ, Rₘₐₓ), wherein the first terminals or second terminals of said at least one resistive memory element and said second resistive memory element are coupled together.

6. The memory device of claim 5, wherein said first terminals or second terminals are coupled together via an intermediate node (313), said memory cell further comprising a transistor (350) coupled between the intermediate node (313) and a read voltage level, wherein during said read phase said control circuitry is adapted to activate said transistor to apply a voltage between said third terminal of said second resistive memory element and at least one of said first and second terminals of said second resistive memory element.

7. The memory device of claim 5, further comprising a latch (306) having:
a first input node (312) coupled to the third terminal (C) of said at least one resistive memory element; and
a second input node (314) coupled to the third terminal (C) of said further second resistive memory element.

8. The memory device of claim 7, wherein said latch further comprises first and second inverters (316, 318, 360, 362) cross-coupled between said first and second input nodes.

9. The memory device of claim 8, wherein:
said first inverter comprises a first single transistor (316), coupled between said first input node (312) and a first supply voltage;
said second inverter comprises a second single transistor (318), coupled between said second input node (314) and said first supply voltage; and
the latch further comprises a third transistor (324) coupled between said first input terminal and a second supply voltage and adapted to have a lower threshold voltage than the first single transistor of said first inverter, and a fourth transistor (326) coupled between said second input terminal and said second supply voltage, and adapted to have a lower threshold voltage than the second single transistor of said second inverter.

10. The memory device of claim 8, wherein said latch further comprises a fifth transistor (320) coupled between said first input node (312) and a data input (321) of said latch, the fifth transistor being controlled by a clock signal (CLK).

11. The memory device of claim 7, further comprising a sixth transistor (322) coupled between said first and second input nodes and activated during a portion of said read phase.

12. The memory device of claim 1, wherein each memory cell of the array further comprises a second transistor (510) coupled between the third terminal of said at least one resistive memory element and a corresponding third row/column line, wherein said control circuitry is adapted to activate said second transistor of a memory cell to be read during said read phase.
